(19) United States
(12) Patent Application Publication
(10) Pub. No.: US 2012/0273792 A1
(43) Pub. Date: Nov. 1, 2012

(54) Zone Melt Recrystallization of Thin Films

(75) Inventors: Larry Hendler, San Jose, CA (US); Sharone Zehavi, San Jose, CA (US); De Phuoc Ly, San Jose, CA (US)

(73) Assignee: INTEGRATED PHOTOVOLTAIC, INC., San Jose, CA (US)

(21) Appl. No.: 13/234,316

(22) Filed: Sep. 16, 2011

Related U.S. Application Data
(63) Continuation-in-part of application No. 13/010,700, filed on Jan. 20, 2011.
(60) Provisional application No. 61/296,799, filed on Jan. 20, 2010.

(51) Int. Cl. H01L 29/04; C30B 13/20; C30B 13/24; C30B 13/16

(52) U.S. Cl. 257/75; 117/43; 257/E29.003

(57) ABSTRACT

A solar cell comprises a recrystallized layer wherein the recrystallized layer has at least one crystal grain at least 90% of the size of the illuminated area of the solar cell.

### PRIORITY

This application is a Continuation-in-Part of U.S. Ser. No. 13/010,700 filed on Jan. 20, 2011 and claims priority from U.S. Provisional Application 61/296,799 filed on Jan. 20, 2010.

### CROSS-REFERENCE TO RELATED APPLICATIONS

This application is related in part to U.S. application Ser. Nos. 12/074,651, 12/720,153, 12/749,160, 12/789,357, 12/860,048, 12/860,088, 12/950,725, 13/010,700, 13/019,965, 13/073,884, 13/077,870, 13/214,158 and U.S. Pat. No. 7,789,331; all owned by the same assignee and incorporated by reference in their entirety herein. Additional technical explanation and background is cited in the referenced material.

### BACKGROUND OF THE INVENTION

1. Field of the Invention

The invention relates generally a process for achieving large grain growth in thin films with specific application to preparation of silicon layers for use in a photovoltaic device.

2. Description of Related Art

Zone melt recrystallisation (ZMR) has been discussed and implemented in many applications requiring the formation of a high quality, low fault, crystal lattice after a material has been produced with substandard crystalline properties. Examples of this application are thin film depositions in solar cell fabrication or flat panel display devices. In both these cases, if the deposition is amorphous, there is a need to recrystallize the surface to achieve the required electrical properties of the device.

The basic requirement of ZMR is to generate enough localized heat in order to melt a portion of the deposited material and to continue melting fresh material entering the zone as material leaving the zone solidifies and recrystallizes according to the crystalline structure of the material behind the melt zone, which acts as a seed. Common methods, well documented in the literature use either a high power halogen lamp focused on the surface undergoing ZMR or a carbon strip heating element, heated by passing a high current through the strip, relying on the resistance of the carbon to generate heat. Both of these applications are capable of ZMR, but require significant control, and are not easily implemented in a manufacturing environment. Additionally halogen lamp and carbon strip heating elements require significant base heaters to raise the overall temperature of the devices being processed to around 1000-1200° C. at which point, the ZMR is able to effectively recrystallize a layer of a few microns thickness, typically 2 to 5 μm.

Another common application is based on excimer lasers and is in use for thin film transistor (TFT) flat panel displays (FPDs). The deposition for TFT FPDs deposits a layer of amorphous silicon typically measured in nm as compared to an optimum layer thickness of approximately 30 microns in solar applications. Excimer laser recrystallisation, as performed for TFT applications result in crystal domains of approximately 0.1 micron. The crystal domains needed in solar applications in order to achieve the necessary electronic properties are of an order of mm to cm. For solar applications of ZMR the energy must propagate into the silicon layer. In other words ZMR implementation in solar applications is a volume process, significantly differentiating it from existing excimer laser based ZMR.

K. Yamamoto in “Thin film crystalline silicon solar cells”, JSAP International, No. 7, January 2003, points out desirable material characteristics for polycrystalline, thin film solar cells. For an open circuit voltage, Voc, above 500 mV, grain size and carrier life time must be optimized; for instance at a grain size of about 0.1 micron, recombination velocity at grain boundaries must be less than 1,000 cm/s. Yamamoto points out several processing parameters that are beneficial for achieving these properties, namely, hydrogen passivation of the grains, low oxygen content and <110> orientation or at least preferred <110> orientation. Yamamoto is incorporated herein in its entirety by reference.

U.S. Pat. No. 7,645,337 discloses a complex method for providing polycrystalline films having a controlled microstructure; preferred orientation of a thin silicon film is achieved with complex optics and a precise laser pattern. Exemplary melt zones are found in the prior art as shown in FIGS. 1, 2 and 3. FIG. 1 is from Fraunhoffer ISE, by Eyer, A; Haas, F; Kieliba, T; “A Zone Melting Recrystallisation (ZMR) Processor for 400 mm Wide Samples,” 19^{th} European Photovoltaic Solar Energy Conference, 7-11 Jun. 2004. Eyer, et al. focus on thin 5 μm layers, upon which a thicker layer is epitaxially grown. The melt mechanism is based on a very focused line melt which creates a high thermal gradient. Outside the line melt, the recrystallization process begins immediately; Eyer reports a melt zone of 1-1.5 mm as shown in FIG. 1. FIG. 2 is an example from this laboratory utilising a melt line width less than 1 mm to achieve a narrow melt of approximately 1 mm wide. In all cases, the recrystallized surface looks like FIG. 2. We see a distinct recrystallization pattern of elongated crystals following the direction of the melt zone propogation that is typical for all methods demonstrated, whether it is Graphite ribbon, Laser ZMR, or Halogen ZMR. FIG. 3 is from equipment manufacturer, TCZ, a subsidiary of Cymer. Excimer lasers are used to generate thin film silicon recrystallization capable of generating crystals approximately 10 microns long all three cases shown are for a “thin”, about 1 mm wide, melt zone with rapid recrystallization.

Prior art in this area also includes studies on grain growth at elevated temperature by E. A. Holm, et al.; “How Grain Growth Stops:”; Science 328, 1138 (2010; incorporated herein in its entirety by reference. Holm publishes results for a computer simulation using a synthetic-driving force molecular dynamics method for nickel recrystallization. S. Hayashi, et al. in “Formation of High Crystallinity Silicon Films by High Speed Scanning of Melting Region Formed by Atmospheric Pressure DC Arc Discharge Micro-Thermal-Plasma-Jet and its Application to Thin Film Transistor Fabrication”; Applied Physics Express 3, 2010, 061401, discloses lateral grains with a maximum grain size of about 60 microns achieved by high speed scanning of a molten region in amorphous silicon, a-Si. Irradiation time was about 1.4 to 1.8 ms; melt duration was about 0.5 ms and recrystallization times were about 0.5 ms or less; reported grain sizes were about 5 microns wide by 60 microns long in the direction of the plasma jet travel. U.S. 2008/0268566 discloses a plurality of heat sources for accelerating zone melting; no consideration is given to cooling time constraints. All references cited are incorporated herein in their entirety by reference.

Additional prior art is found in U.S. Pat. No. 7,749,819, U.S. Pat. No. 7,888,247, U.S. Pat. No. 7,914,619, U.S. 2009/0256057, U.S. 2011/0175099, U.S. Pat. No. 6,322,625, U.S. Pat. No. 7,645,337, U.S. 2008/0023070, U.S. 2008/0202576, U.S. 2008/0202577, U.S. 2008/0268566, U.S. 2010/0132779, U.S. 2010/0178435, U.S. 2011/0192461, and U.S. 2010/0190288. All references cited are incorporated herein in their entirety by reference.

Conventional solar cells remain costly. There is a need to improve conversion efficiency by means of low cost processing. Increasing grain size substantially above conventional techniques is a technique to improve conversion efficiency and lower cost. The instant invention discloses a device structure and method of formation applicable to solar cells and all thin film based devices including display panels and other devices requiring larger grain sizes.

### BRIEF SUMMARY OF THE INVENTION

One embodiment of the instant invention is based on a linear array of diode lasers working at 805 nm wavelength; optionally, a Coherent 4000L diode laser. A radiation source configured in a linear array may be imaged across the length of a surface being processed, optionally a 156 mm, ≈6 in., for standard pseudo square solar cells; optionally a flat panel for large area displays. The goal is to create a zone along an axis of the device, perpendicular to the direction of travel of a substrate or motion of a heat source, preferably extending across the entire extent of the substrate. This heated zone melts the surface layer, optionally silicon, deposited on the substrate, optionally, capped by an oxide layer to prevent agglomeration of melted layer into balls. In one embodiment, a laser line, heating the zone, scans across the surface of the wafer using, optionally, a rotating mirror, a galvo controlled mirror, a robotic arm moving the entire laser head, or a motion control system moving a substrate underneath the laser line. By moving an optical beam relative to the surface at a rate of, for instance, 1 mm/sec, the beam can be configured to melt all surface area entering the line scan or irradiated zone, while the surface exiting the heated zone solidifies; in some embodiments the layer recrystallizes in alignment with the crystal lattice of the material behind the melt zone, optionally <100> or <110> or other orientation. In some embodiments a preferred recrystallization orientation is to the [100] plane. In one embodiment a 5 mm wide zone extends across a substrate in a direction perpendicular to the substrate or heating source travel; a 1 mm/sec travel rate corresponds to a 5 sec. time in the irradiated zone for a given point on the substrate; optionally a melt zone may be more or less than 5 mm wide and the travel rate may be more or less than 1 mm/sec; optionally a zone may be 3 mm wide and a travel rate 0.5 mm/sec. As solid state device process technology improves cell sizes will increase to flat panel dimensions, or larger. One of the advantages of linear arrays of laser diodes is the ability to increase the line length by adding additional diodes to the array. A key feature of the disclosed invention is that the substrate must be heated to a temperature T_{R} such that sufficient time, Y, is spent above a specified temperature X*T_{MP}, as the deposited layer cools below its melting point, T_{MP}, after a portion of the deposited layer travels out of a molten zone; X is a fraction applied to the deposited layer's melting point, and Y is the time from leaving the molten zone until the layer reaches a temperature of about X*T_{MP}. In some embodiments X is between about 0.5*T_{MP} and about 0.99*T_{MP} or about 50% of the melting point of the deposited layer and 99% of T_{MP}; factors determining this range include the material system, desired size of crystal grains and time allocated for the ZMR process.

### BRIEF DESCRIPTION OF THE SEVERAL VIEWS OF THE DRAWING(S)

FIG. 1 shows a 1 mm molten zone of the prior art.

FIG. 2 shows exemplary exemplary crystal structure of the prior art.

FIG. 3 shows exemplary exemplary crystal structure of the prior art from an equipment vendor.

FIGS. 4A and B shows schematic diagram of lamp based heater.

FIG. 5 shows exemplary surface structure of an embodiment of the instant invention.

FIG. 6 shows exemplary faceting in a standard [100] silicon wafer.

FIG. 7 shows exemplary faceting in a recrystallized deposited layer of one embodiment of the instant invention.

FIG. 8 shows exemplary faceting in a non-recrystallized deposited layer.

FIG. 9A shows schematic of exemplary heating zones. FIG. 9B shows exemplary temperature profile across the zones.

FIG. 10 shows exemplary process steps for exemplary structures comprising one or more recrystallized layers.

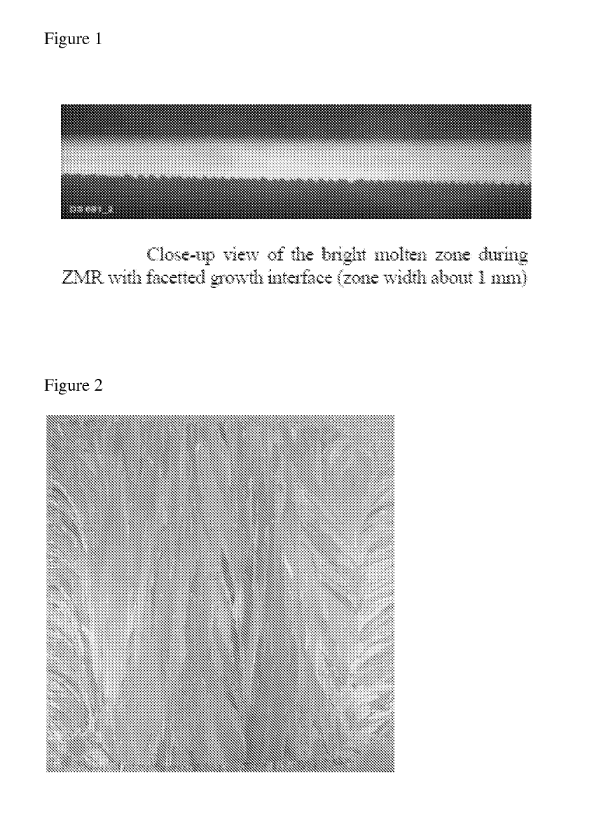

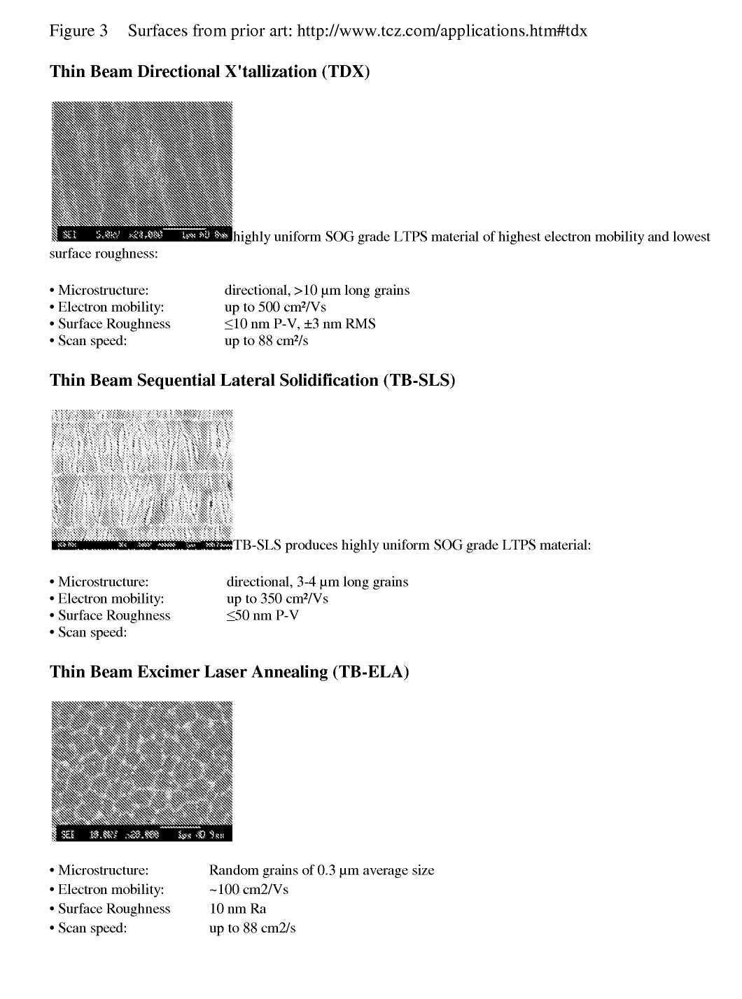

### DETAILED DESCRIPTION OF THE INVENTION

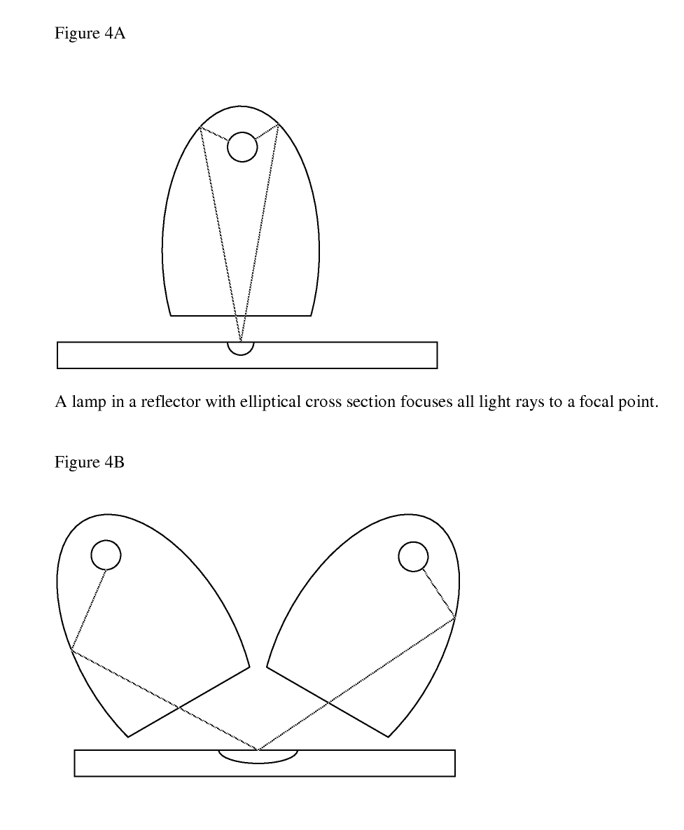

In some embodiments a radiation source may illuminate a zone of a surface being processed. An optical system is implemented to keep the beam in focus at all points of the line; two exemplary systems are shown in FIGS. 4A and B. The energy of the beam is adjusted to result in a continuous melt of the surface layer in the area illuminated by the beam. The beam may be moved relative to the surface at a rate of approximately 1 mm/sec; optionally, other scanning rates are feasible based on properties of a heating system and deposited layer material. Light beam(s) continue to melt all unmelted surface area entering the line scan, while the surface exiting the line scan solidifies and recrystallizes, optionally, in alignment with the crystal lattice of the material already recrystallized. In the case of silicon on SiO₂ a preferred orientation resulting from the disclosed process is [100]. In some embodiments a heated zone is generated using appropriate cylindrical optics. Another implementation of the method could generate the line by using diffractive optics. Optionally, a means for heating is stationary and a substrate is moved or advanced through various heating zones; optionally only one zone, I, is heated or irradiated with a means for heating sufficient to achieve a molten line across a substrate with a deposited layer. As the deposited layer is advance out of the irradiated zone the melted region will start to solidify and recrystallize; the most critical step is the time the recrystallizing region, R, is above a predetermined temperature, X*T_{MP}; below this predetermined temperature, X*T_{MP}, for all practical purposes grain growth is slowed dramatically.

Some embodiments of the disclosed method use a means for heating a substrate to maintain a heated zone, S, at some minimum temperature, Ts, above about 50% of the melting point, 0.5 T_{MP}, on either side of the melt zone. In some embodiments Ts is between about 0.50 T_{MP} and about 0.95 T_{MP} depending on the film thickness, grain size desired, film composition and power of the means for heating in the irradiated zone, I. Ts may be at room ambient if a means for heating in zone I is sufficiently intense that an acceptably large region can be heated to above its melting point within the time allotted; when this is not the case then Ts must arrive above 20° C. In some embodiments a film surface and typically the substrate being processed is elevated to temperature Ts, a minimum time before melting and a second minimum time after melting. This has the advantage of reducing the power requirements of the laser or other source performing the ZMR, and, in some instances, reducing the thermal stresses generated by high temperature gradients in substrates. It is a critical step in the process that the deposited thin film layer be maintained above a minimum temperature for a minimum time, Y, immediately after solidification.

In some embodiments of the disclosed invention for a silicon layer the substrate is heated to a temperature of about 1200° C. such that sufficient time, Y, is spent above a specified temperature 0.85*T_{MP}, after the deposited layer cools below 1420° C., T_{MP}, after it travels out of the molten zone, where 0.85 is the fraction applied to the deposited layer's melting point, and Y, the time from leaving the molten zone until the layer cools to a temperature of about 0.85*T_{MP} is about 30 seconds for a travel speed, Q, of about 0.5 mm/sec.

FIGS. 4A and B show exemplary lamps in a reflector with elliptical cross section focusing all light rays to a focal point. With normal incidence, the focal line is at its narrowest giving the highest energy density to create a line melt. A wide melt zone is created by implementing two line sources focused, using ellipsoidal reflectors, to a common line. The two sources are angled towards the surface causing an expansion of the focus, which is at its narrowest when the light is normally incident to the surface. By rotating the line heater and adding a second line heater, the available energy is increased and the focal width of the line is increased.

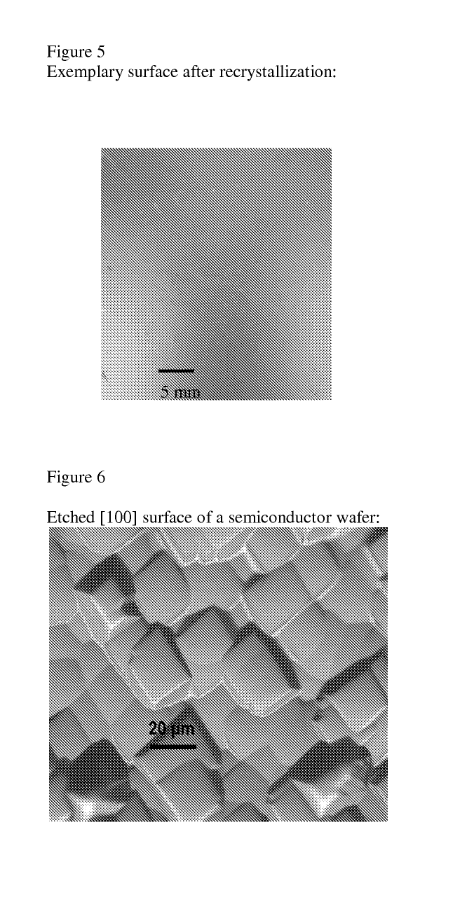

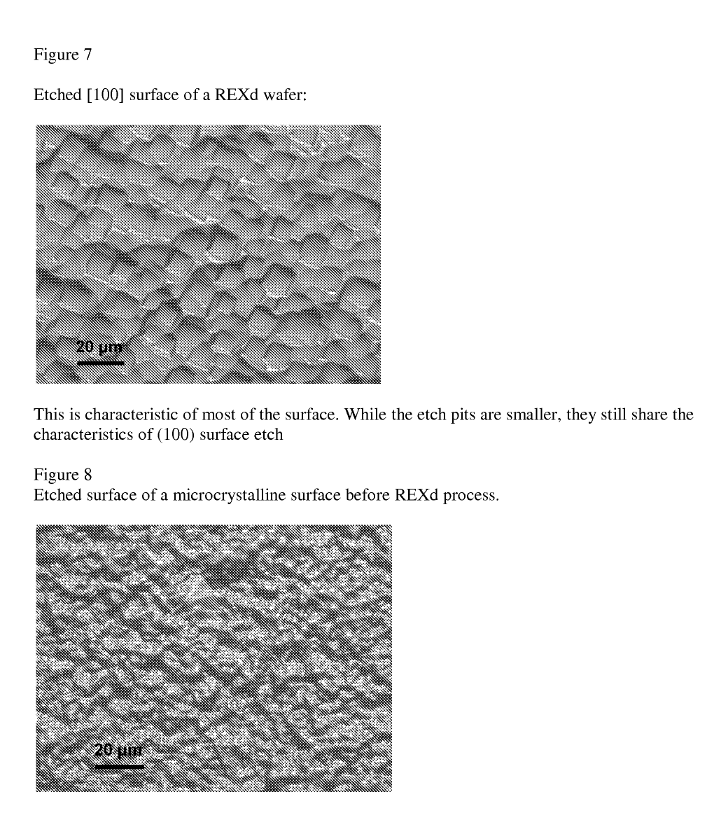

FIG. 5 shows exemplary deposited silicon layers after recrystallization; the surface has been etched in KOH, 1:1 by weight H₂O, at 80° C. for 3 min. FIG. 6 shows a standard quality semiconductor wafer etched similarly; note the [100] facets. FIG. 7 shows exemplary deposited silicon layers after recrystallization etched similarly; note the [100] facets. In this embodiment a Si deposited layer on SiO₂, about 30 microns thick and a wide melt line, about 10-15 mm; this compares to 1-2 mm wide of the prior art. In addition to the wide melt zone, a high substrate temperature of about 1200° C., Ts, creates a slow recrystallization step on the order of 10-20 seconds for Y. In doing so we create a large surface recrystallization that has the appearance of a single crystal recrystallization. In some embodiments Y is between about 0.1 and about 1 sec.; in some embodiments Y is between about 1 and about 3 sec.; in some embodiments Y is between about 3 and about 5 sec.; in some embodiments Y is between about 5 and about 10 sec.; in some embodiments Y is between about 10 and about 30 sec.; in some embodiments Y is between about 0.1 and about 5 sec. depending upon preferred crystal size, material system and process time limitation.

FIG. 8 shows exemplary etched surface of a microcrystalline surface before REXd process. The surface structure is very random with no specific characteristic or direction in the etch.

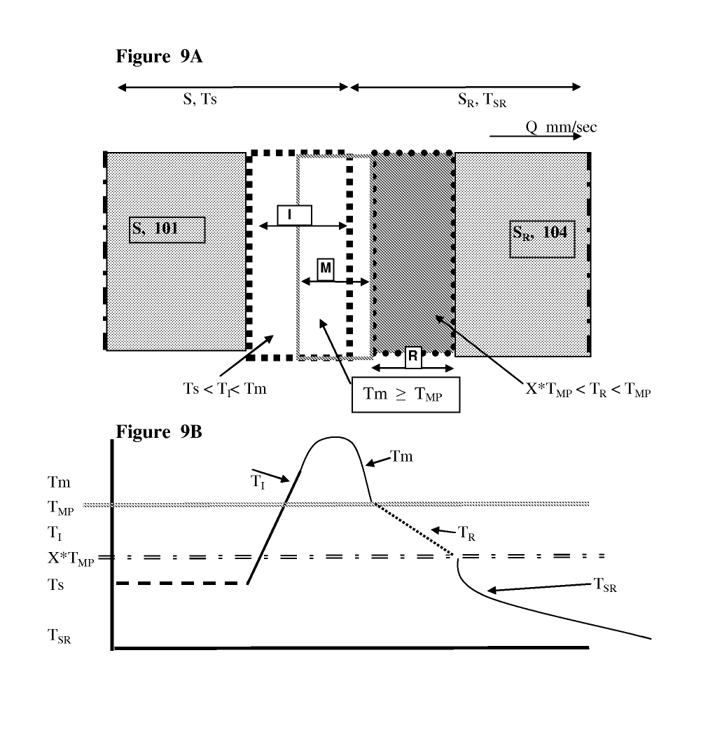

FIG. 9A shows an embodiment wherein a substrate with deposited layer, 101, is conveyed from left to right schematically in the figure passing through the various zones at a rate of Q, mm/sec. When needed, Zone S may comprise a means for heating operable to heat the substrate to Ts. A second means for heating, optionally, radiative, irradiates Zone I, such that the temperature of the deposited layer achieves T₁ within Zone I and Tm within Zone M, wherein T₁ is greater than T_{S} and T_{M} is greater than T_{MP}; in some embodiments T_{MP} of the deposited layer occurs immediately inside the irradiated zone; when this happens it usually means that Ts can be lowered; however it is preferable that T_{MP} of the deposited layer occurs within Zone I. As substrate with deposited layer, 101 moves out of irradiated Zone I the molten region begins to cool, either naturally or assisted; optionally zones R and/or Zone S_{R} may comprise a means for modulating zone temperature including a means for heating and a means for cooling. When the deposited layer temperature reaches T_{R}, defined as below T_{MP}, solidification and recrystallization begin. Recrystallization continues for at least a minimum time period Y until T_{R} falls below X*T_{MP}, defined as the temperature at the trailing edge of Zone R and the leading edge of Zone S_{R}; the trailing edge of Zone S_{R} is at T_{SR}; X*T_{MP} is also defined as the temperature below which the rate of recrystallization is immaterial to the functionality of the intended device; where T_{M}≧T_{MP}>T_{R}≧X*T_{MP}>T_{SR}. T_{SR} may be different from T_{S} depending upon the composition of the deposited layer and the recrystallization requirements. In some embodiments Zones S, R and/or S_{R} may require no external or supplementary heaters depending upon the capability of the means for heating in Zone I; optionally, Zone R may require a means for cooling when “natural” cooling effects are insufficient or one desires a faster throughput rate Q while still maintaining the constraint on minimum time Y. Based upon the material system and temperatures employed, Y ranges from less than about 0.1 seconds to about 30 seconds; note time in Zone R must be equal to or greater than Y seconds and therefore Zone R must be at least Y*Q mm long in the direction of travel of the substrate.

In some embodiments some amount of supercooling occurs; in general supercooling is preferred. The factors controlling the amount of supercooling comprise the surface finish of the substrate, the material system, the cleanliness of the substrate and deposited film, impurities present, particularly ones with a melting point above the m.p. of the deposited layer, vibrations of the equipment, and any factor that influences or generates nucleation sites. In some embodiments T_{S} may be greater than X*T_{MP} and T_{SR} may be much lower than T_{S}. FIG. 9B shows schematically one embodiment and the associated temperature profiles of the deposited layer as it moves through recrystallization steps of process 1000.

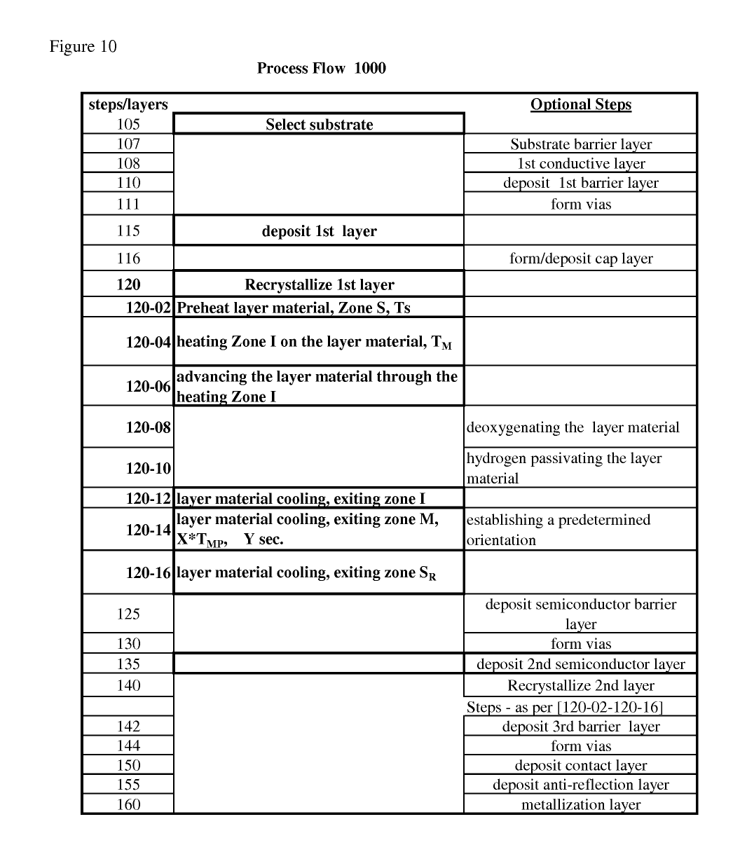

As shown FIG. 10, some embodiments comprise multiple layers and multiple process steps; some layers and steps are optional. FIG. 10 shows an exemplary embodiment of Process 1000, comprising required steps 105 of selecting a substrate, 115, depositing a first layer; and 120 recrystallizing the first layer, comprising steps 120-02 through 120-16. All other steps are optional and may or may not be used in any particular embodiment. For the instant invention at least one layer is recrystallized; steps 120 and 140 comprising steps 1202 through 1216 are steps available for recrystallization. Deoxygenating may be done with increased temperature in a low pressure environment or with a getter step; hydrogen passivating may be done with a hydrogen atmosphere at a temperature above about 800° C.; establishing a preferred orientation may be done with a seed crystal or selective substrate texturing or selected composition of the top most substrate layer; it is known that [100] silicon will preferentially form on a SiO₂ surface.

In some embodiments a substrate is chosen from a group consisting of silicon, graphite, graphite foil, glassy graphite, impregnated graphite, pyrolytic carbon, pyrolytic carbon coated graphite, flexible foil coated with graphite, graphite powder, carbon paper, carbon cloth, carbon, glass, alumina, carbon nanotube coated substrates, carbide coated substrates, graphene coated substrates, silicon-carbon composite, silicon carbide, SiO₂ coated substrate and mixtures or combinations thereof. In some embodiments a barrier layer comprises one or more layers of a composition chosen from a group consisting of Si, SiO₂, Al₂O₃, TaN, TiO₂, silicon carbides, silicon nitrides, metal oxides, metal carbides, metal nitrides and conductive ceramics and mixtures or combinations thereof. In all embodiments described herein it is contemplated that a substrate may be a discrete object such as a conventional semiconductor wafer or similar size object of a different material; alternatively, a substrate may be a flat plate such as one used for making large area solar cells or display devices; alternatively, a substrate may be a long strip, optionally, flexible; alternatively, a substrate may be a “continuous” strip of material to facilitate a roll-to-roll process.

In some embodiments a method of recrystallizing a layer of material comprises the steps: selecting a substrate with the layer deposited onto the substrate; advancing the substrate through first zone, S, such that a temperature, T_{S}, is established within at least a portion of the deposited layer wherein Ts is less than the melting point, T_{MP}, of the layer; advancing the substrate through second zone, I, such that a temperature, T_{I}, is established within at least a portion of the deposited layer wherein T_{I} is greater than T_{S}; advancing the substrate through third zone, M, such that a temperature, T_{M}, is established within at least a portion of the deposited layer wherein T_{M} is greater than T_{MP}; and advancing the substrate through fourth zone, R, such that a temperature, T_{R}, is established within at least a portion of the deposited layer wherein T_{R} is below T_{MP}, of the deposited layer and above a predetermined temperature, X*T_{MP}, for at least Y seconds wherein the substrate and layer are advanced through the first through fourth zones sequentially at a rate of about Q mm/sec. such that the temperature criteria of each zone is established within at least a portion of the deposited layer while that portion is physically within the respective zone; optionally, X is between about 0.99 and about 0.60; optionally, Y is between about 0.1 and about 30 seconds; optionally, the second zone comprises one or more means for heating chosen from a group consisting of a spot of radiation rapidly scanned over the substrate, a linear array of radiation projected onto the substrate, laser, flash lamp, resistance heaters, rf coils, microwave radiation, and infra-red heaters; optionally, the first and third zones comprise one or more means for temperature modulation chosen from a group consisting of a spot of radiation rapidly scanned over the substrate, a linear array of radiation projected onto the substrate, laser, flash lamp, resistance heaters, rf coils, microwave radiation, infra-red heaters and means for cooling comprising refrigeration coils, thermoelectric means, fans, and cooling coils; optionally, the deposited layer material is substantially one or more elements chosen from a group consisting of Group II, III, IV, V and VI elements; optionally, the second and third zone length combined are more than 5 mm long in the direction of substrate travel; optionally, the substrate advancing rate, Q, is at least 0.5 mm per second.

In some embodiments a solid state device comprises a substrate; and a first layer comprising material recrystallized by the method of claim 1; optionally, the first layer comprises material recrystallized such that more than 90% of the recrystallized layer has crystal grains of a size greater than 100 microns in any lateral dimension parallel to the substrate surface; optionally, the first layer comprises material recrystallized such that more than 90% of the recrystallized semiconductor layer has crystal grains of a size greater than 50% of the smallest lateral dimension parallel to the substrate surface; optionally, the recombination velocity is between about 50 cm/s and about 500 cm/sec; optionally, a solid state device is a solar cell wherein the recrystallized layer comprises a crystal grain at least 90% of the size of the irradiated area of the solar cell or at least 90% of the size of an individual cell in a large area solar module; optionally, the substrate is chosen from a group consisting of silicon, silicon composite with graphite, glass, ceramic, carbon, and a material coated with SiO₂ or SiC; optionally, a solid state device further comprises a barrier layer between the substrate and the first layer.

It will be understood that when an element as a layer, region or substrate is referred to as being “on” or “over” or “adjacent” another element, it can be directly on the other element or intervening elements may also be present. In contrast, when an element is referred to as being “directly on” or “directly over” or “in contact with” another element, there are no intervening elements present. It will also be understood that when an element is referred to as being “connected” or “coupled” to another element, it can be directly connected or coupled to the other element or intervening elements may be present. In contrast, when an element is referred to as being “directly connected” or “directly coupled” to another element, there are no intervening elements present.

The foregoing described embodiments of the invention are provided as illustrations and descriptions. They are not intended to limit the invention to a precise form as described. In particular, it is contemplated that functional implementation of invention described herein may be implemented equivalently in various combinations or other functional components or building blocks. Other variations and embodiments are possible in light of above teachings to one knowledgeable in the art of semiconductors, thin film deposition techniques, and materials; it is thus intended that the scope of invention not be limited by this Detailed Description, but rather by Claims following.

We claim:

1. A method of recrystallizing a layer of material comprising the steps:
selecting a substrate with the layer deposited onto the substrate;
advancing the substrate through first zone, S, such that a temperature, T_{S}, is established within at least a portion of the deposited layer wherein Ts is less than the melting point, T_{MP}, of the layer;
advancing the substrate through second zone, I, such that a temperature, T_{I}, is established within at least a portion of the deposited layer wherein T_{I} is greater than T_{S};
advancing the substrate through third zone, M, such that a temperature, T_{M}, is established within at least a portion of the deposited layer wherein T_{M} is greater than T_{MP}; and
advancing the substrate through fourth zone, R, such that a temperature, T_{R}, is established within at least a portion of the deposited layer wherein T_{R} is below T_{MP}, of the deposited layer and above a predetermined temperature, X*T_{MP}, for at least Y seconds wherein the substrate and layer are advanced through the first through fourth zones sequentially at a rate of about Q mm/sec. such that the temperature criteria of each zone is established within at least a portion of the deposited layer while that portion is physically within the respective zone.

2. The method of claim 1 wherein X is between about 0.99 and about 0.60.

3. The method of claim 1 wherein Y is between about 0.1 and about 30 seconds.

4. The method of claim 1 wherein the second zone comprises one or more means for heating chosen from a group consisting of a spot of radiation rapidly scanned over the substrate, a linear array of radiation projected onto the substrate, laser, flash lamp, resistance heaters, rf coils, microwave radiation, and infra-red heaters.

5. The method of claim 1 wherein the first and third zones comprise one or more means for temperature modulation chosen from a group consisting of a spot of radiation rapidly scanned over the substrate, a linear array of radiation projected onto the substrate, laser, flash lamp, resistance heaters, rf coils, microwave radiation, infra-red heaters and means for cooling comprising refrigeration coils, thermoelectric means, fans, and cooling coils.

6. The method of claim 1 where the deposited layer material is substantially one or more elements chosen from a group consisting of Group II, III, IV, V and VI elements.

7. The method of claim 1 wherein the second and third zone length combined are more than 5 mm long in the direction of substrate travel.

8. The method of claim 1 wherein the substrate advancing rate, Q, is at least 0.5 mm per second.

9. A solid state device comprising;
a substrate; and
a first layer comprising material recrystallized by the method of claim 1.

10. A solid state device of claim 9 wherein the first layer comprises material recrystallized such that more than 90% of the recrystallized layer has crystal grains of a size greater than 100 microns in any lateral dimension parallel to the substrate surface.

11. A solid state device of claim 9 wherein the first layer comprises material recrystallized such that more than 90% of the recrystallized semiconductor layer has crystal grains of a size greater than 50% of the smallest lateral dimension parallel to the substrate surface.

12. A solid state device of claim 9 wherein the recombination velocity is between about 50 cm/s and about 500 cm/sec.

13. A solid state device of claim 9 operable as a solar cell wherein the recrystallized layer comprises a crystal grain at least 90% of the size of the irradiated area of the solar cell.

14. A solid state device of claim 9 wherein the substrate is chosen from a group consisting of silicon, silicon composite with graphite, glass, ceramic, carbon, and a material coated with SiO₂ or SiC.

15. A solid state device of claim 9 further comprising a barrier layer between the substrate and the first layer.
